(19) United States
(12) Patent Application Publication
(10) Pub. No.: US 2005/0282317 A1
(43) Pub. Date: Dec. 22, 2005

(54) Thin film semiconductor apparatus and method for driving the same

(75) Inventor: Hiroyuki Ikeda, Kanagawa (JP)

Correspondence Address: ROBERT J. DEPKE;LEWIS T. STEADMAN, TREXLER, BUSHNELL, GLANGLORGI, BLACKSTONE & MARR, 105 WEST ADAMS STREET, SUITE 3600, CHICAGO, IL, 60603-6299, US

(73) Assignee: Sony Corporation

(21) Appl. No.: 11/166,867

(22) Filed: Jun. 24, 2005

Related U.S. Application Data
(62) Division of application No. 09/821,636, filed on Mar. 29, 2001.

(30) Foreign Application Priority Data
Mar. 29, 2000 (JP) JP2000-090282

(51) Int. Cl. H01L 29/04

(52) U.S. Cl. 438/149

(57) ABSTRACT

A thin film semiconductor apparatus comprising thin film transistors integrated on a substrate, and a wiring connecting the thin film transistors to one another, wherein each of the thin film transistors comprises a channel which has a predetermined threshold-voltage and on-off operates depending on a gate voltage applied through a wiring, wherein at least a part of the thin film transistors comprises a semiconductor thin film constituting the channel, and a first gate electrode and a second gate electrode disposed on a surface and a back surface of the semiconductor thin film through an insulating film, wherein the first and second gate electrodes receive a first gate voltage and a second gate voltage, respectively, through wirings which are separately provided, wherein the first gate electrode on-off controls the channel depending on the first gate voltage, and wherein the second gate electrode actively controls the threshold voltage depending on the second gate voltage to render the on-off operation of the thin film transistors appropriate. The semiconductor apparatus of the present invention is advantageous in that the threshold voltage can be actively controlled in accordance with the-dispersion of the threshold voltage, so that an increase in consumed power, an erroneous operation and the like can be suppressed. Thus, it is possible to stably provide a high performance threshold voltage circuit array in high yield.

### BACKGROUND OF THE INVENTION

1. Field of the Invention

The present invention relates to a thin film semiconductor apparatus employed for a driving substrate of a liquid crystal display, an organic electroluminescence display or the like, and a method for driving the same. More particularly, the present invention is concerned with a technique for controlling threshold voltages of thin film transistors integrated in a thin film semiconductor apparatus.

2. Description of the Related Art

In the thin film transistors integrated in a thin film semiconductor apparatus, amorphous silicon or polycrystalline silicon is used in an active layer. With respect to the amorphous silicon, conventionally, a processing technique has been established in which an amorphous silicon thin film transistor is formed in a large area on a glass substrate which is inexpensive. Also with respect to the polycrystalline silicon, due to the development of a laser anneal crystallization method and the introduction of the above processing technique established for the amorphous silicon thin film transistor, it has been possible to form a polycrystalline silicon thin film transistor in a large area on an inexpensive glass substrate. The thin film semiconductor apparatus having a large area can particularly be applied to an active matrix liquid crystal display. In the active matrix liquid crystal display containing the thin film semiconductor apparatus in which a polycrystalline silicon thin film transistor is used, by virtue of the excellent ability of the polycrystalline silicon thin film transistor to drive a current, both a switching device for pixels using the thin film transistor and a peripheral driving circuit can be integrally formed on the same substrate.

By the way, the structures of the thin film transistors are roughly classified into two types. One type is a top gate structure such that a gate electrode is formed on the upper portion of an active layer comprised of a semiconductor thin film on a substrate, and another type is a bottom gate structure such that a gate electrode is formed on the lower portion of an active layer. Circuits constituted by thin film transistors having the top gate structure or bottom gate structure are generally of a complementary type such that a p-type in which a switch is opened by the current flow by a negative gate voltage based on the source and an n-type in which a switch is opened by a positive gate voltage are combined, i.e., the so-called complementary metal-oxide semiconductor (hereinafter, frequently referred to simply as “CMOS”) circuit. The CMOS circuit has an advantageous feature such that the consumed power is particularly small. The recent active matrix liquid crystal display has incorporated thereinto a CMOS driving circuit on the periphery of a pixel array in which a pixel electrode and a thin film transistor for switching are integrated. In this liquid crystal display, there is no need to provide an integrated circuit (IC) for driving on the outside. Therefore, it is considered that the whole production cost for this display is low, as compared to that for the active matrix liquid crystal display in which the switching device for driving pixels is formed by an amorphous silicon thin film transistor. In the future, it is expected that the crystalline of polycrystalline silicon be improved, so that the thin film semiconductor apparatus in which the polycrystalline silicon thin film transistors are integrated is improved in ability to drive a current, and can be operated with a lower threshold voltage (Vₜₕ).

Under the above circumstances, for achieving the supply at a low cost of a thin film semiconductor apparatus in which the polycrystalline silicon thin film transistors which can be operated with a lower threshold voltage are integrated, the following problems are encountered. The first problem is as follows. When the above thin film semiconductor apparatus is used for a display device, such as a liquid crystal display or an organic electroluminescence display, a glass substrate in a large size is used. As a process for forming a gate insulating film on such a large-size substrate, a plasma chemical vapor deposition (hereinafter, frequently referred to simply as “CVD”) process is generally used. However, a film deposited by the plasma CVD process contains therein a charge, hydrogen (H), a hydroxyl (OH) group and the like. Therefore, the properties of the transistor are disadvantageous in that the threshold voltage Vₜₕ may be varied and likely to be changed with time. The second problem is as follows. In polycrystalline silicon obtained by crystallizing. amorphous silicon by a laser annealing method or the like, the crystalline characteristic may be varied due to fluctuations of the radiation conditions of laser beam and the like. In other words, the mobility of carriers is fluctuated. The effect of this fluctuation of the mobility of carriers on the thin film semiconductor apparatus is large, and thus, generally, the threshold voltage Vₜₕ may be varied in the range of from about 1 to 2 V.

When the performance of the polycrystalline silicon thin film transistor is improved and the threshold voltage Vₜₕ is lowered without removing such factors of the dispersion of the threshold voltage Vₜₕ, a disadvantageous phenomenon occurs such that, although the thin film transistor should be in an off-state, it is in an on-state due to the dispersion of the properties, causing the circuit to erroneously operate. Several methods for solving such a problem have been conventionally proposed. For example, there is a method in which, in the thin film transistor constituting a CMOS circuit, different conductive impurities for adjusting the threshold voltage Vₜₕ are implanted into n-type and p-type active layers, respectively. In this case, the erroneous operation of the circuit is prevented by shifting the threshold voltage Vₜₕ of the n-channel type thin film transistor in the positive direction and shifting the threshold voltage Vₜₕ of the p-channel type thin film transistor in the negative direction. For example, boron is implanted into the n-channel, and phosphorus is implanted into the p-channel. However, when boron and phosphorus as impurities for adjusting the threshold voltage Vₜₕ are separately implanted into the channels, the numbers of the photolithography step for forming a mask and the impurity introduction step are increased, thus causing an increase of the production cost. Further, the threshold voltage Vₜₕ increased for preventing the erroneous operation causes the ability of the polycrystalline silicon thin film transistor to drive a current to be poor, so that the advantage of the improvement of the performance of the polycrystalline silicon thin film transistor is disadvantageously lowered. As another method for solving the above problem and for lowering the production cost without increasing the number of the steps for forming a CMOS, there is a method in which a switching device for pixel array portion and a peripheral driving circuit are constituted only by an n-channel type thin film transistor (NMOS) or a p-channel type thin film transistor (PMOS). An example of the method in which a circuit is constituted only by a PMOS is disclosed in, for example, Unexamined Japanese Patent Application Laid-Open Specification No. 9-18011. However, when a circuit is constituted only by an NMOS or a PMOS, conditions for controlling the erroneous operation caused by the dispersion of the threshold voltage Vₜₕ and the power consumption are more limited.

From the above background, the development of a technique for solving the problem of the erroneous operation caused by the dispersion of the threshold voltage Vₜₕ is being desired. As the technique taking the initiative, with respect to the switching device for pixel array portion, a structure is proposed in which a light screening film is provided on the back surface of a thin film transistor, especially a thin film transistor having a top gate structure. In Unexamined Japanese Patent Application Laid-Open Specification No. 5-257164, for example, a light screening film is provided on the back surface of the active layer to prevent the switch from being erroneously turned on due to a light leakage current. In addition, a technique is also proposed in which a positive constant voltage is applied, also for electrically shielding, to a light screening film made of a metal disposed on the back surface of the active layer, which is on the opposite side of the gate electrode. Further, Unexamined Japanese Patent Application Laid-Open Specification No. 9-90405 proposes a technique in which a light screen film made of a metal disposed on the back surface is used as a gate electrode and the same potential as that of the gate electrode on the surface side is applied thereto. The structure used in this technique resembles a dual gate structure which is known as a device structure in the case where a memory is formed using a silicon wafer. The dual gate structure is one that is obtained by forming a pair of gate electrodes opposite to each other on and under the active layer through insulating films. In the thin film transistor having this dual gate structure, by performing the on-off operation of the transistor by constantly applying the same voltage to both the upper and lower gate electrodes, a driving current higher than that in the thin film transistor having a single gate structure can be obtained.

### SUMMARY OF THE INVENTION

In any of the above conventional techniques, only the erroneous operation caused by a leakage current is suppressed or only an on-current is increased by employing a dual gate drive. By contrast, the present invention is not made merely for solving the problem about the fluctuations of the properties due to an increase in leakage current but for meeting the strong demands for solving the problems caused by the dispersion of the threshold voltage Vₜₕ relate to the above-mentioned polycrystalline silicon thin film transistor, particularly when the performance of the polycrystalline silicon thin film transistor is improved.

An object of the present invention is to provide means to solve the above-mentioned problems accompanying the prior art. According to one embodiment of the present invention, there is provided a thin film semiconductor apparatus comprising thin film transistors integrated on a substrate, and a wiring connecting the thin film transistors, wherein each of the thin film transistors comprises a channel which has a predetermined threshold voltage and on-off operates depending on a gate voltage applied through a wiring, and at least a part of the thin film transistors comprises a semiconductor thin film constituting the channel, and a first gate electrode and a second gate electrode, which are disposed on a surface and the other surface of the semiconductor thin film having an insulating film in between. The first gate electrode and the second gate electrode receive a first gate voltage and a second gate voltage, respectively, through wirings which are separately provided, and the first gate electrode on-off controls the channel depending on the first gate voltage, and the second gate electrode actively controls the threshold voltage depending on the second gate voltage to adjust the on-off operation of the thin film transistors. The semiconductor thin film constituting the channel of the present invention may be comprised of polycrystalline silicon which does not contain an impurity effectively affecting the formation of a depletion layer, and has a thickness of 100 nm or less. Alternatively, the semiconductor thin film constituting the channel of the present invention may be comprised of polycrystalline silicon which contains an impurity effectively affecting the formation of a depletion layer, and has a thickness two times or less the maximum of the thickness of the depletion layer. Furthermore, the second gate electrode of the present invention may actively controls the threshold voltage depending on the second gate voltage applied at least when the thin film transistors off-operate, to thereby decrease a current flowing through the channel when the thin film transistors off-operate, as compared to a current flowing through the channel when the said second gate voltage is not applied. Alternatively, the second gate electrode of the present invention may actively controls the threshold voltage depending on the second gate voltage applied at least when the thin film transistors on-operate, to thereby increase a current flowing through the channel when the thin film transistors on-operate, as compared to a current flowing through the channel when the second gate voltage is not applied.

According to another embodiment of the present invention, there is provided a liquid crystal display comprising a pair of substrates disposed so as to have a predetermined gap, and a liquid crystal kept in the gap, one of the substrates containing thereon a display portion in which a pixel electrode and a thin film transistor for driving the pixel electrode are integrated, and a peripheral circuit portion in which thin film transistors are integrated, the other of the substrates containing thereon an opposite electrode which faces the pixel electrode, each of the thin film transistors comprising a channel which has a predetermined threshold voltage and on-off operates depending on a gate voltage applied through a wiring, at least a part of the thin film transistors comprising a semiconductor thin film constituting the channel, and a first gate electrode and a second gate electrode, which are disposed on a surface and the other surface of the semiconductor thin film sandwiching an insulating film. The first gate electrode and the second gate electrode of the present invention receive a first gate voltage and a second gate voltage, respectively, through wirings which are separately provided, and the first gate electrode on-off controls the channel depending on the first gate voltage, and the second gate electrode actively controls the threshold voltage depending on the second gate voltage to adjust the on-off operation of the thin film transistors.

According to another embodiment of the present invention, there is provided an electroluminescence display comprising a substrate having thereon a display portion in which an electroluminescence device and a thin film transistor for driving the electroluminescence device are integrated, and a peripheral circuit portion in which thin film transistors are integrated, each of the thin film transistors comprising a channel which has a predetermined threshold voltage- and on-off operates depending-on a gate voltage applied through a wiring, at least a part of the thin film transistors comprising a semiconductor thin film constituting the channel, and a first gate electrode and a second gate electrode, which are disposed on a surface and the other surface of the semiconductor thin film having an insulating film in between. The first gate electrode and the second gate electrode of the present invention receive a first gate voltage and a second gate voltage, respectively, through wirings which are separately provided, and the first gate electrode on-off controls the channel depending on the first gate voltage, and the second gate electrode actively controls the threshold voltage depending on the second gate voltage to adjust the on-off operation of the thin film transistors.

According to another embodiment of the present invention, a first gate electrode (a front surface electrode, for example) and a second gate electrode (a rear surface electrode, for example) in a thin film transistor of a dual gate structure receive a first gate voltage and a second gate voltage, respectively, through separate wirings provided for each electrode. The first gate electrode controls On-Off operation of the channel in accordance with the first gate voltage in the same way as that of a conventional gate electrode while the second gate electrode actively controls a threshold voltage Vₜₕ with using the second gate voltage, which is different from the first gate voltage, for adjustment so as to properly control On-Off operation of the thin film transistor. For example, the second gate electrode may actively controls the threshold voltage by using the second gate voltage applied during the Off operation, so as to limit a leak current flowing through the channel during the Off operation. Alternatively, the second gate electrode may actively controls the threshold voltage by using the second gate voltage applied during the On operation, so as to increase a driving current flowing through the channel during the On operation. As mentioned above, it is necessary to induce effect on a band structure of the channel with not only the first gate voltage but also the second gate voltage in order to actively control the threshold voltage in accordance with the On-Off operation. To realize and maintain such an operation status stable, it is preferable to have a comparably thin thickness at a portion of the semiconductor thin film constituting the channel region. If the semiconductor thin film constituting the channel is comprised of polycrystalline silicon which does not contain an impurity effectively affecting the formation of a depletion layer, it is preferable for the semiconductor thin film to have a thickness of 100 nm or less. Furthermore, if the semiconductor thin film constituting the channel region (an active layer) is comprised of polycrystalline silicon which contains an impurity effectively affecting the formation of a depletion layer, it is preferable for the semiconductor thin film to have a thickness two times or less the maximum of the thickness of the depletion layer. By satisfying the above mentioned conditions, it is possible to actively control the threshold voltage Vₜₕ of the thin film transistor in accordance with the On-Off operation by separately controlling the first gate voltage and the second gate voltage.

### BRIEF DESCRIPTION OF THE DRAWINGS

The foregoing and other objects, features and advantages of the present invention will be apparent to those skilled in the art from the following description of the presently preferred exemplary embodiments of the invention taken in connection with the accompanying drawings, in which:

FIG. 1 is a partially diagrammatic cross-sectional view showing a thin film semiconductor apparatus according to one embodiment of the present invention;

FIGS. 2A and 2B are diagrammatic views illustrating the operation principle of the present invention;

FIGS. 3A and 3B are graphs showing the operation principle of the present invention;

FIGS. 4A and 4B are graphs showing the operation principle of the present invention;

FIG. 5A is a circuit diagram showing one example of the thin film semiconductor apparatus of the present invention, and FIG. 5B is one showing an example of the corresponding conventional thin film semiconductor apparatus;

FIG. 6A is a circuit diagram showing another example of the thin film semiconductor apparatus of the present invention, and FIG. 6B is one showing an example of the corresponding conventional thin film semiconductor apparatus;

FIG. 7 is a circuit diagram showing still another example of the thin film semiconductor apparatus of the present invention;

FIG. 8 is a partially diagrammatic cross-sectional view showing a thin film semiconductor apparatus according to another embodiment of the present invention;

FIG. 9 is a diagrammatic perspective view showing an example of the active matrix liquid crystal display of the present invention; and

FIG. 10 is a partially diagrammatic cross-sectional view showing an example of the organic electroluminescence display of the present invention.

### DETAILED DESCRIPTION OF THE PREFERRED EMBODIMENT

Hereinbelow, preferred embodiments of the present invention will be described in detail with reference to the accompanying drawings, but the embodiments should not be construed as limiting the scope of the present invention.

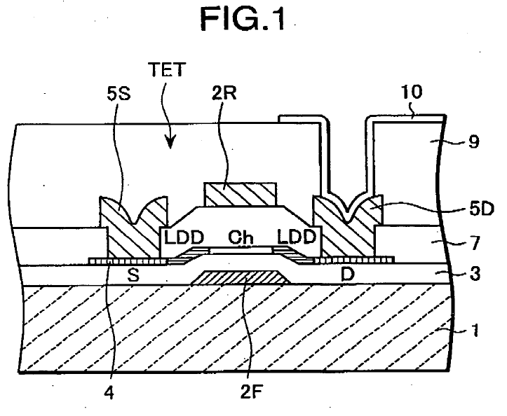

FIG. 1 is a partially diagrammatic cross-sectional view showing a thin film semiconductor apparatus according to one embodiment of the present invention. As shown in FIG. 1, the thin film semiconductor apparatus of the present invention comprises thin film transistors TFT integrated on a substrate 1 comprised of glass or the like, and a wiring connecting the thin film transistors to one another. The thin film transistor TFT has a channel Ch which has a predetermined threshold voltage (Vₜₕ) and on-off operates depending on a gate voltage applied through a gate wiring (not shown). At least a part of the thin film transistors TFT comprises a semiconductor thin film 4 constituting the channel Ch, and a first gate electrode (front gate electrode 2F) and a second gate electrode (rear gate electrode 2R), which are disposed on a surface and a back surface of the semiconductor thin film 4 through insulating films 3, 7. The thin film transistor TFT shown in FIG. 1 has a bottom gate structure. Therefore, the inherent gate electrode disposed under the semiconductor thin film 4 is used as the front gate electrode 2F, and the additional gate electrode disposed on the side opposite to the front gate electrode 2F is used as the rear gate electrode 2R. The front gate electrode 2F and the rear gate electrode 2R receive a first gate voltage and a second gate voltage, respectively, through wirings (not shown) which are separately provided. The front gate electrode 2F on-off controls the channel Ch depending on the first gate voltage, whereas the rear gate electrode 2R actively controls the threshold voltage Vₜₕ depending on the second gate voltage to render the proper on-off operation of the thin film transistor TFT. A contact hole is opened in the insulating film 7 which covers the thin film transistor TFT, and a source electrode 5S and a drain electrode 5D are formed thereon. The above-mentioned rear gate electrode 2R is also formed on the insulating film 7. The thin film transistor TFT having the bottom gate structure having the above construction is coated with a planarization film 9, and a pixel electrode 10 is formed thereon. In addition, in the semiconductor thin film 4, lightly doped drain (hereinafter, frequently referred to simply as “LDD”) regions having implanted thereinto an impurity with a low concentration are respectively provided between a source S and the channel Ch and between a drain D and the channel Ch. In this embodiment, the semiconductor thin film 4 constituting the channel Ch is comprised of polycrystalline silicon which does not contain an impurity effectively affecting the formation of a depletion layer, and has a film thickness of 100 nm or less. Alternatively, the semiconductor thin film 4 constituting the channel Ch may be comprised of polycrystalline silicon which contains an impurity effectively affecting the formation of a depletion layer, and may have a film thickness two times the maximum of the thickness of the depletion layer or less. In a specific operation, for example, the rear gate electrode 2R actively controls the threshold voltage Vₜₕ depending on the second gate voltage applied at least when the thin film transistor TFT off-operates, to thereby decrease a leakage current flowing through the channel Ch when the thin film transistor TFT off-operates, as compared to a leakage current flowing when the second gate voltage is not applied. Further, the rear gate electrode 2R may actively control the threshold voltage Vₜₕ depending on the second gate voltage applied at least when the thin film transistor TFT on-operates, to thereby increase a driving current flowing through the channel Ch when the thin film transistor TFT on-operates, as compared to a driving current flowing when the second gate voltage is not applied.

Next, an example of the process for fabricating the thin film semiconductor apparatus of the present invention is described also with reference to FIG. 1. First, molybdenum (Mo) is deposited on a substrate 1 made of glass or the like by a sputtering process so as to have a thickness of 100 nm, and the resultant film is subjected to patterning in the predetermined form, to thereby form a front gate electrode 2F and a gate wiring (not shown) connected to the front gate electrode 2F. Then, a silicon oxide (SiO₂) film is deposited thereon by a plasma CVD process so as to have a thickness of 150 nm, to thereby form a gate insulating film 3. Further, amorphous silicon (a-Si) is continuously deposited thereon so as to have a thickness of 50 nm. The resultant product is subjected to annealing at 400 ° C. for 2 hours so that hydrogen contained in the amorphous silicon is eliminated therefrom, and then, subjected to excimer laser annealing (ELA), to thereby convert the amorphous silicon to polycrystalline silicone, thus forming a semiconductor thin film 4 comprised of polycrystalline silicone.

Then, SiO₂ is deposited (not shown) so as to have a thickness of, for example, 50 nm, and boron for adjusting the threshold voltage Vₜₕ is introduced into the semiconductor thin film 4 by an ion implantation process. The concentration is controlled so that the effective boron concentration of the channel Ch becomes, for example, about 5×10¹⁶/cm³. Subsequently, a resist pattern is formed with a self alignment method using the front gate electrode 2F by the back-exposure processing. Further, phosphorus as an impurity is implanted by an ion implantation process using the resist pattern as a mask, to thereby form an LDD region. The dose is, for example, 1×10¹³/cm². After removal of the resist, on the n-channel type thin film transistor TFT shown in FIG. 1, another resist pattern is formed so as to be larger than the thin film transistor TFT in the longitudinal-direction of the channel by about 1 μm from the gate edge and to completely cover a p-channel type thin film transistor (not shown). Using this resist pattern as a mask, phosphorus as an impurity is introduced by an ion doping process with a dose of 1×10¹⁵/cm², to thereby form a source S and a drain D of the shown n-channel type thin film transistor TFT. After removal of the used resist pattern, still another resist pattern is formed so as to completely cover the n-channel type thin film transistor and to cover the channel Ch in the p-channel type thin film transistor. Using this resist pattern as a mask, boron as an impurity is introduced by an ion doping process with a set dose of 8×10¹⁴/cm², to thereby form a p-channel type thin film transistor TFT. After removal of the used resist pattern, the impurities implanted in the semiconductor thin film 4 are activated by a lamp anneal method. Then, the semiconductor thin film 4 is separated in an island form in accordance with the form of the device region of the thin film transistor TFT. Then, SiO₂ is deposited by a plasma CVD process so as to have a thickness of 150 nm, and further, Si₃N₄ S is deposited thereon so as to have a thickness of 200 nm, to thereby form an interlayer insulating film 7. In this state, the resultant product is subjected to annealing at 400 ° C. for 1 hour. Then, a contact hole connected to the gate wiring, the source S and the drain D is formed in the interlayer insulating film 7, and aluminum and titanium are continuously deposited thereon so as to have thickness of 400 nm and 100 nm, respectively. The resultant multi-layer metal film is subjected to patterning in the predetermined form, to thereby form a signal wiring 5S, a rear gate electrode 2R and a drain electrode 5D in appropriate positions. The rear gate electrode 2R can be made from a material which is totally different from the materials for the signal wiring 5S and the like. Then, a planarization film 9 made of an acrylic resin or the like, having a thickness of about 1 μM, is formed. Subsequently, a transparent electrode, such as an ITO film or the like, is deposited on a pixel array portion and subjected to patterning in the predetermined form, to thereby form a pixel electrode 10. In the thin film transistor TFT formed in this thin film semiconductor apparatus, the depletion layer maximum thickness of an active layer which is to be the channel Ch is about 140 nm, and the thickness of the semiconductor thin film 4, i.e., 50 nm corresponds to two times or less the above maximum depletion layer thickness. When this thin film semiconductor apparatus is used as a driving substrate for an active matrix display, thin film transistors for a driving circuit are integrated not only in the shown pixel array portion but also in a periphery portion (not shown). It is preferred that the top and bottom gate structure in the present invention is applied to the n-channel type thin film transistor disposed in a position which is strictly restricted to the threshold voltage Vₜₕ in the driving circuit. In this case, all of the thin film transistors contained in the pixel array portion (display portion) and the peripheral circuit portion are constructed so that the semiconductor thin film 4 constituting the channel Ch contains the same conductive impurity effectively affecting the formation of a depletion layer. Thus, the step for impurity implantation can be omitted. Alternatively, all of the thin film transistors contained in the display portion and the peripheral circuit portion may be constructed so that the semiconductor thin film 4 constituting the channel Ch does not contain an impurity effectively affecting the formation of a depletion layer.

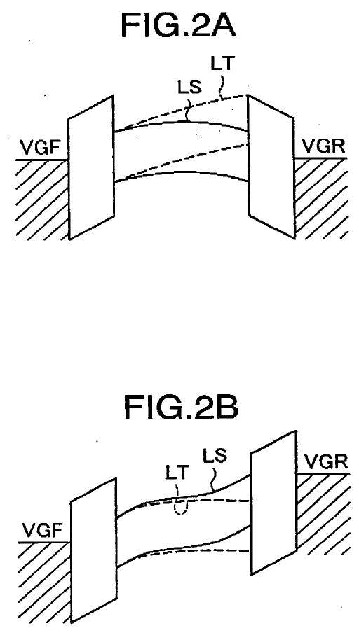

Next, the background and the basic principle of the present invention are described with reference to FIGS. 2A and 2B. In general, in the case where an effective impurity is introduced into silicon, namely, the Fermi energy is shifted from the center of the conduction band edge and the valence band edge, when an electric field is applied, a large number of carriers are removed. For example, in the case where boron is introduced, when a weak positive gate voltage is applied to silicon through a gate insulating film, a hole which is a positive charge is removed from the silicon interface, so that the so-called depletion layer is formed. Further, when the gate voltage is increased, an electron is excited, thus causing strong inversion conditions. The strong inversion conditions cause the thickness of the depletion layer to be saturated. Such a phenomenon is changed to another phenomenon when the silicon layer has a smaller thickness and a gate electrode is present also on the back surface through an insulating film. The present invention utilizes this phenomenon. In the case where an impurity (for example, boron) is introduced into silicon and the thickness of the silicon layer is two times or less the maximum of the thickness of the depletion layer, as shown in FIG. 2A, when a positive voltage is applied to both the surface and the back surface of the silicon layer, the depletion layers interfere with each other as indicated by a band LS. Thus, the band LS in the silicon layer is further changed. A band LT shows a state such that the thickness of the silicon layer is two times or more the maximum of the thickness of the depletion layer. In addition, as shown in FIG. 2B, when positive and negative gate voltages which are inverse to each other are individually applied to the surface and the back surface of the silicon layer, for example, a negative voltage is applied to the back surface of the silicon layer, the depletion layer on the surface side becomes short as indicated by a band LS. In FIGS. 2A and 2B, characters “VGR” represent a gate voltage on the surface side (front gate voltage), and characters “VGF” represent a gate voltage on the back side (rear gate voltage). The phenomenon shown in FIGS. 2A and 2B is observed also when an impurity is not introduced, and in such a case, the phenomenon occurs irrespective of the thickness of the silicon layer. For controlling in an actual gate voltage, it is preferred that the thickness of silicon is 100 nm or less.

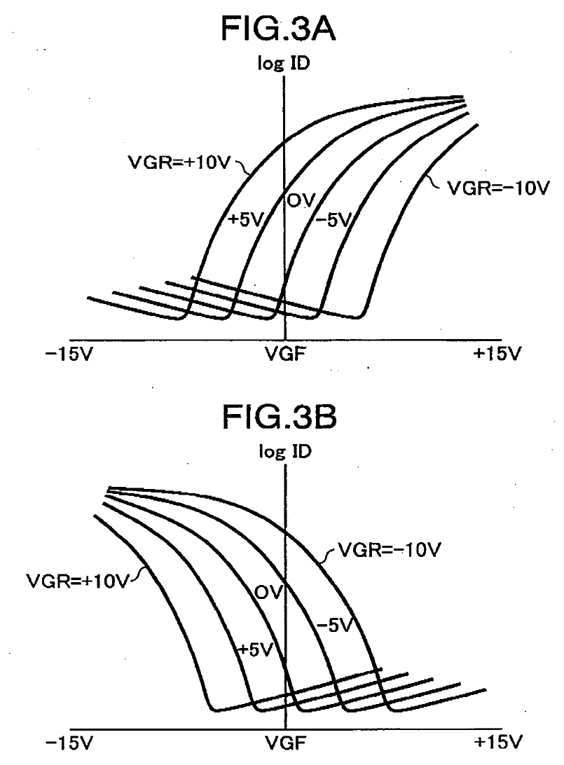

Thus, by utilizing a phenomenon such that the band in silicon is largely changed depending on the front gate voltage VGF, VGR applied to the surface and the back surface of the silicon layer, it becomes possible to actively control the threshold voltage Vₜₕ of the thin film transistor. This point is described with reference to FIGS. 3A and 3B. FIG. 3A is a graph showing the operation characteristics of the n-channel type thin film transistor in the present invention shown in FIG. 1. The front gate voltage VGF is taken as the abscissa, and the drain current ID is taken as the ordinate on the logarithm scale. In addition, the rear gate voltage VGR is used as a parameter. FIG. 3B is a graph showing the operation characteristics of the p-channel type thin film transistor in the present invention. When the rear gate voltage VGR is set, for example, at intervals at −10 V, −5 V, 0 V, +5 V and +10 V, and the front gate voltage VGF is applied continuously from −10 V to +10 V, the drain current/gate voltage characteristics are shifted step by step in both the n-channel type thin film transistor and the p-channel type thin film transistor. This phenomenon is remarkably observed when the semiconductor thin film constituting the channel contains an impurity effectively affecting the formation of a depletion layer and has a thickness two times or less the maximum of the thickness of the depletion layer. The above phenomenon is also remarkably observed when the semiconductor thin film constituting the channel does not contain an impurity effectively affecting the formation of a depletion layer and has a thickness of 100 nm or less. That is, when the semiconductor thin film constituting the channel has a relatively small thickness, the phenomenon shown in FIGS. 3A and 3B occurs.

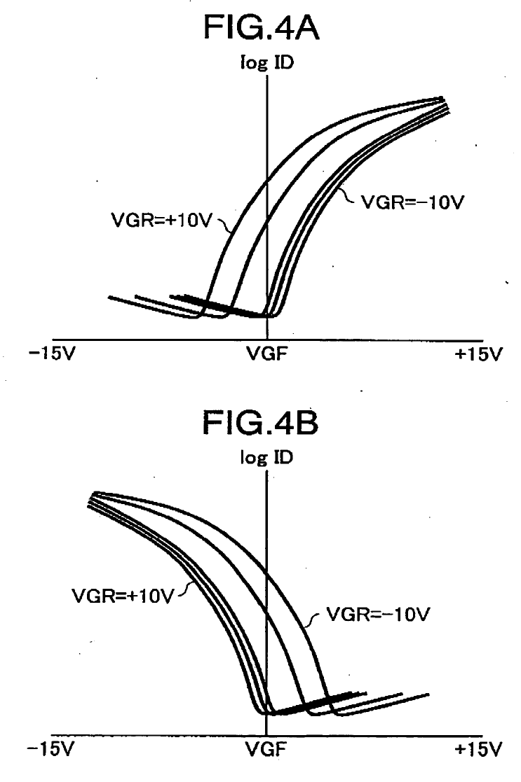

By contrast, FIGS. 4A and 4B show a phenomenon occurs when the semiconductor thin film constituting the channel has a relatively large thickness. FIG. 4A shows the drain current/gate voltage characteristics of an n-channel type thin film transistor, whereas FIG. 4B shows the drain current/gate voltage characteristics of a p-channel type thin film transistor. In this case, even when the rear gate voltage VGR is set at intervals at −10 V, −5 V, 0 V, +5 V and +10 V and the front gate voltage VGF is applied continuously from −10 V to +10 V, only a part of the operation characteristics curve is changed step by step. In the n-channel type thin film transistor, when the rear gate voltage VGR is negative, there is almost no effect on the drain current/gate voltage characteristics. In the p-channel type thin film transistor, when the rear gate voltage VGR is positive, there is almost no effect on the drain current/gate voltage characteristics of the thin film transistor.

In the present invention, the threshold voltage Vₜₕ of the thin film transistor is actively controlled utilizing the basic properties shown in FIGS. 3A and 3B. For example, in the n-channel type thin film transistor in a circuit, when the consumed power is increased or the circuit erroneously operates due to a leakage current of the transistor, the same voltage as the front gate voltage is applied to the rear gate electrode as usual with timing at which the transistor is in an on-state and a negative potential is applied to the rear gate electrode with timing at which the transistor is in an off-state. Thus, even though the threshold voltage Vₜₕ of the n-channel type thin film transistor is shifted to the negative side due to the dispersion thereof, the leakage current can be completely shielded. When the rear gate voltage VGR is 0 V, the threshold voltage Vₜₕ is low and the leakage current is large, but, it is found that appropriate off-operation characteristics shown in FIG. 3A can be obtained by lowering the rear gate voltage VGR to −5 V. Thus, by applying the rear gate voltage VGR of −5 V at least when the transistor is in an off-state, an proper operation can be secured even when the threshold voltage Vₜₕ is dispersed. When the transistor is in an on-state, there is no particular problem even when the same potential as the front gate voltage is not applied but a potential of 0 V is applied to the rear gate electrode.

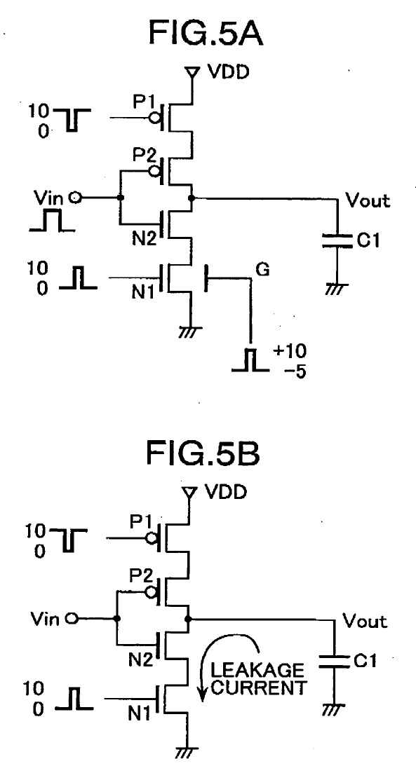

Further, in the p-channel type thin film transistor in which the threshold voltage Vₜₕ is slightly shifted to the negative side, an operation can be performed in which when the transistor is in an on-state, a negative potential is applied to both the front and rear gate electrodes to shift the threshold voltage Vₜₕ, to thereby increase the current, and, when the transistor is in an off-state, a potential of 0 V is applied to the rear gate electrode. As mentioned above, by individually applying gate voltage pulses to each of the front and rear gate electrodes, it is possible to actively control the threshold voltage Vₜₕ depending on the respective circuits and stably, effectively operate the circuits despite of the dispersion of the threshold voltage Vₜₕ. Further, it is also possible to increase the on-current, as compared to that in the case of the single gate electrode structure. FIG. 5A is a circuit diagram showing an illustrative example of the thin film semiconductor apparatus of the present invention, and FIG. 5B is one showing an example of the corresponding conventional thin film semiconductor apparatus. This example of the present invention is a representative example of a clock-controlled inverter constituting the shift register incorporated as a peripheral driving circuit for an active matrix display. In FIGS. 5A and 5B, a pulse of +10 V is input to an n-channel type thin film transistor N1 at a selection time and a pulse of 0 V is input at a non-selection time. A pulse is input to a p-channel type thin film transistor P1 in reverse, that is, a pulse of 0 V is input to the p-channel type thin film transistor P1 at a selection time and a pulse of +10 V is input at a non-selection time. The signal transmitted from the previous stage of the shift register is applied to an input terminal Vᵢₙ of a pair of thin film transistors N2, P2 which are inverter-connected to one another. An output Vₒᵤₜ of the inverter at a non-selection time is a non-fixed potential. When inverters N2, P2 are selected by the clock input applied to the front gates of the p-channel type thin film transistor P1 and the n-channel type thin film transistor N1 and the input terminal Vᵢₙ is at +10 V, the output Vₒᵤₜ becomes 0 V by the n-channel type thin film transistors N1, N2. The potential of the output Vₒᵤₜ is fixed at +10 V by release of the selection. When the input terminal Vᵢₙ is at 0 V, the output Vₒᵤₜ is fixed at +10. V by the p-channel type thin film transistors P1, P2. However, when the performance of the transistor is improved and the threshold voltage Vₜₕ of the n-channel type thin film transistor is lowered to about 1 V, the threshold voltage Vₜₕ of the n-channel type thin film transistor is varied around 0 V due to the dispersion of the properties of polycrystalline silicon. In such a case, when the output Vₒᵤₜ is fixed at +10 V, the fixed voltage of the output Vₒᵤₜ is lowered due to a large leakage current of the n-channel type thin film transistors N1, N2, so that the ability to transmit a signal to the subsequent stage is deteriorated and this deterioration is accumulated every stage, thus causing an erroneous operation in the signal transmission of the shift register. In this example, for avoiding this phenomenon, as shown in FIG. 5A, a rear gate electrode G is provided on the n-channel type thin film transistor N1. A pulse of +10 V is input to this rear gate electrode G at a selection time and a pulse of −5 V is input at a non-selection time. Thus, the signal transmission of the shift register is properly conducted.

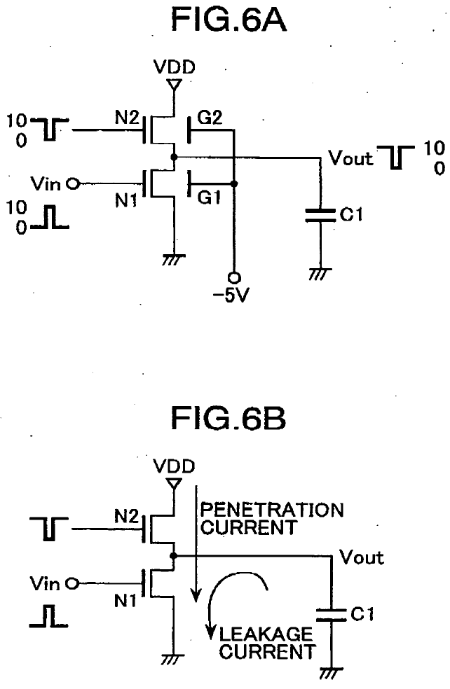

FIG. 6A is a circuit diagram showing another example of the thin film semiconductor apparatus of the present invention, and FIG. 6B is one showing an example of the corresponding conventional thin film semiconductor apparatus. This example of the present invention is also a clock-controlled inverter, but the circuit is constituted only by an n-channel type thin film transistor. A specific example of the production method therefor is substantially the same as the method described above with reference to FIG. 1, except that the steps particularly in connection with the p-channel type thin film transistor are omitted. As shown in FIGS. 6A and 6B, the signal transmitted from the previous stage is input to an input terminal Vᵢₙ of a thin film transistor N1. A clock pulse of 0 V at a selection time and +10 V at a non-selection time is input to another thin film transistor N2. When the input terminal Vᵢₙ is at 0 V, the circuit is in a non-selection state and the output Vₒᵤₜ is at +10 V. When the input terminal Vᵢₙ is at +10 V, the circuit is in a selection state and the output Vₒᵤₜ is at 0 V. The subsequent stage operates in reverse and signals are successively transmitted. However, in the n-channel type thin film transistor, when the circuit is in a state such that a voltage pulse of 0 V is applied to the front gate electrodes of both the n-channel type thin film transistors N1, N2, a leakage current may flow due to the dispersion of the threshold voltage Vₜₕ. The leakage which occurs in the n-channel type thin film transistor N2 causes an increase in the consumed power, and the leakage which occurs in the n-channel type thin film transistor N1 causes an erroneous operation. For avoiding this disadvantageous phenomenon, in this example, rear gate electrodes G1, G2 are provided on both the thin film transistors N1, N2, and a pulse voltage of −5 V is constantly applied thereto. Thus, the leakage is suppressed, and it is possible to prevent the increase in the consumed power and the erroneous operation.

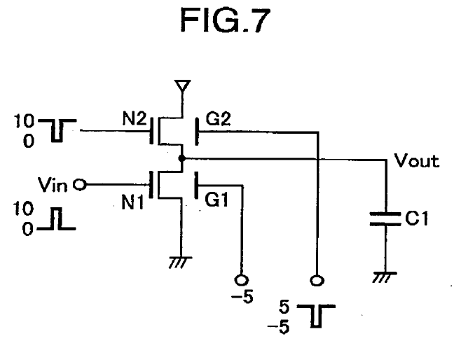

FIG. 7 show a modified example of the clock-controlled inverter shown in FIG. 6A, in combination with a negative regulator. A voltage pulse lower than the voltage applied to a front gate electrode by 5 V is applied to a rear gate electrode G2 of a thin film transistor N2, whereas a pulse voltage of −5 V is constantly applied to a rear gate electrode G1 of a thin film transistor N1.

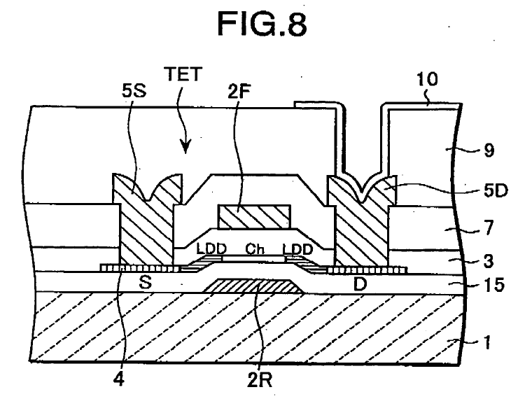

FIG. 8 is a partially diagrammatic cross-sectional view showing a thin film semiconductor apparatus according to another embodiment of the present invention. For an easy understanding, in FIG. 1 and FIG. 8, corresponding parts or portions are indicated by the same reference numerals. Whereas the embodiment shown in FIG. 1 is a thin film transistor having a bottom gate structure, the embodiment shown in FIG. 8 is a thin film transistor having a top gate structure. As shown in FIG. 8, a rear gate electrode 2R is formed on an insulating substrate 1 comprised of glass or the like. A semiconductor thin film 4 comprised of polycrystalline silicon is formed on the rear gate electrode 2R through an underlying insulating film 15. An inherent front gate electrode 2F is formed on the semiconductor thin film 4 through a gate insulating film 3. An interlayer insulating film 7 is deposited so as to cover the front gate electrode 2F, and a signal wiring 5S and a drain wiring 5D are formed thereon by patterning. A planarization film 9 is deposited so as to cover the signal wiring 5S and the drain wiring 5D, and a pixel electrode 10 is formed thereon.

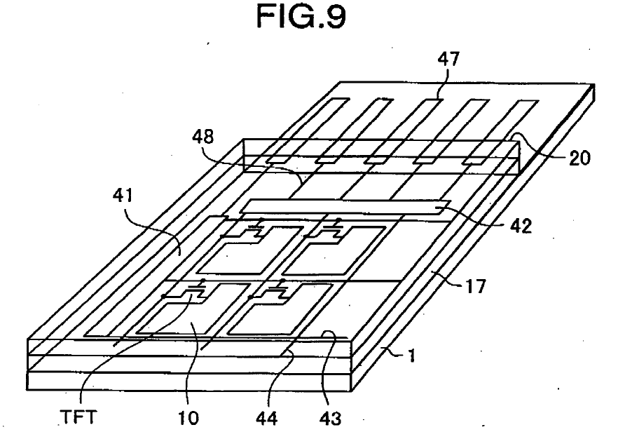

FIG. 9 is a diagrammatic perspective-view showing an example of the active matrix liquid crystal display of the present invention. This liquid crystal display has a structure such that a liquid crystal 17 is kept between a driving substrate 1 and an opposite substrate 20. A pixel array portion and a peripheral circuit portion are integrated on the driving substrate 1. The peripheral circuit portion is divided into a vertical scanning circuit 41 and a horizontal scanning circuit 42. In addition, terminal electrodes 47 for external connection are formed on the upper end side of the driving substrate 1. Each of the terminal electrodes 47 is connected to the vertical scanning circuit 41 and the horizontal scanning circuit 42 through a wiring 48. A gate wiring 43 and a signal wiring 44 which intersect are formed on the pixel array portion. The gate wiring 43 is connected to the vertical scanning circuit 41, and the signal wiring 44 is connected to the horizontal scanning circuit 42. A pixel electrode 10 and a thin film transistor TFT for driving the pixel electrode 10 are formed in the intersecting portion of the wirings 43, 44. On the other hand, an opposite electrode (not shown) is formed on the inner surface of the opposite substrate 20. In this example, the thin film transistor TFT formed on the pixel array portion is of a conventional single gate type, whereas the shift register and the like formed in the peripheral vertical scanning circuit 41 and horizontal scanning circuit 42 are constructed by a thin film transistor having a dual gate structure according to the present invention.

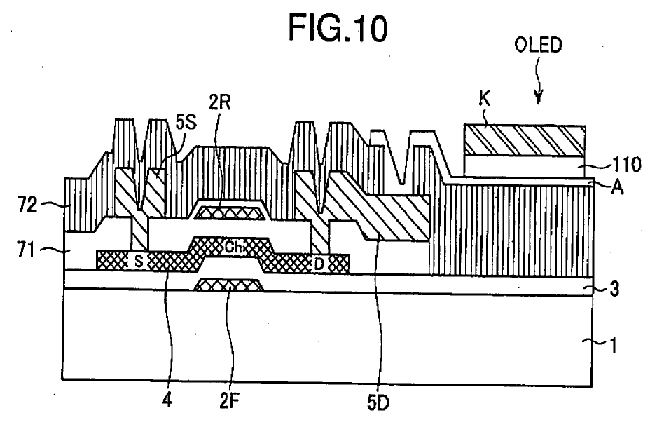

FIG. 10 is a partially diagrammatic cross-sectional view showing an example of the organic electroluminescence display of the present invention, and shows one pixel only. In this example, as an electro-optic device, instead of the liquid crystal cell, an organic electroluminescence device OLED is used. OLED is a device that is obtained by successively laminating together an anode A comprised of a transparent conductive film, such as an ITO film, an organic layer 110 and a cathode K comprised of a metal. The anode A is separated pixel by pixel and basically transparent. The cathode K is connected between the pixels and basically light reflective. When a forward voltage (of about 10 V) is applied to between the anode A and the cathode K of the OLED having the above construction, an implantation of a carrier, such as an electron or a hole, occurs, so that a light emission is observed. It is considered that the operation of the OLED is the light emission caused by an exciton formed from a hole implanted from the anode A and an electron implanted from the cathode K. The OLED emits a light generated by itself from the surface side to the back surface side of a substrate 1 comprised of glass or the like. The thin film transistor shown in FIG. 10 has a dual gate structure such that a front gate electrode 2F and a rear gate electrode 2R are provided according to the present invention.

As mentioned above, in the present invention, the front gate electrode and the rear gate electrode of the thin film transistor respectively receive gate voltages through wirings which are separately provided, and the front gate electrode on-off controls the channel depending on the corresponding gate voltage, whereas the rear gate electrode actively controls the threshold voltage of the thin film transistor depending on the corresponding gate voltage to render the proper on-off operation of the thin film transistor. When the thin film transistor having such a construction is used in a circuit, and particularly, polycrystalline silicon is used in an active layer (channel), it is possible to actively control the threshold voltage due to the marked dispersion of the threshold voltage, so that an increase in consumed power, an erroneous operation and the like can be suppressed, thus making it possible to stably provide a high performance threshold voltage circuit array with a high yield. It is noted that, when the thickness of the active layer is large, it may be difficult to appropriately control the threshold voltage. When the active layer which does not contain an effective impurity has a thickness of 100 nm, or when the active layer which contains an effective impurity has a thickness which is two times or less the maximum depletion layer thickness, the threshold voltage of the thin film transistor can be completely controlled with using the potential of the rear gate electrode.

1-19. (canceled)

20. A method for driving a thin film semiconductor apparatus which comprises thin film transistors integrated on a substrate, and a wiring connecting said thin film transistors, each of said thin film transistors comprising a channel which has a predetermined threshold voltage and on-off operates depending on a gate voltage applied through a wiring, at least a part of said thin film transistors comprising a semiconductor thin film constituting said channel, and a first gate electrode and a second gate electrode, which are disposed on a surface and the other surface of said semiconductor thin film sandwiching an insulating film,
wherein said first gate electrode and said second gate electrode receive a first gate voltage and a second gate voltage, respectively, through wirings which are separately provided,
wherein said first gate electrode on-off controls said channel depending on said first gate voltage, and wherein said second gate electrode actively controls said threshold voltage depending on said second gate voltage to adjust the on-off operation of said thin film transistors.

21. The method according to claim 20, wherein said semiconductor thin film constituting said channel is comprised of polycrystalline silicon which does not contain an impurity effectively affecting the formation of a depletion layer, and has a thickness of 100 nm or less.

22. The method according to claim 20, wherein said semiconductor thin film constituting said channel is comprised of polycrystalline silicon which contains an impurity effectively affecting the formation of a depletion layer, and has a thickness two times or less the maximum of the thickness of said depletion layer.

23. The method according to claim 20, wherein said second gate electrode actively controls said threshold voltage depending on said second gate voltage applied at least when said thin film transistors off-operate, to thereby decrease a current flowing through said channel when said thin film transistors off-operate, as compared to a current flowing through said channel when said second gate voltage is not applied.

24. The method according to claim 20, wherein said second gate electrode actively controls said threshold voltage depending on said second gate voltage applied at least when said thin film transistors on-operate, to thereby increase a current flowing through said channel when said thin film transistors on-operate, as compared to a current flowing through said channel when said second gate voltage is not applied.

25. A method for driving a liquid crystal display which comprises a pair of substrates disposed together having a predetermined gap, and a liquid crystal kept in said gap,
one of said substrates containing thereon a display portion in which a pixel electrode and a thin film transistor for driving said pixel electrode are integrated, and a peripheral circuit portion in which thin film transistors are integrated,
the other of said substrates containing thereon an opposite electrode which faces said pixel electrode,
each of said thin film transistors comprising a channel which has a predetermined threshold voltage and on-off operates depending on a gate voltage applied through a wiring, at least a part of said thin film transistors comprising a semiconductor thin film constituting said channel, and a first gate electrode and a second gate electrode, which are disposed on a surface and the other surface of said semiconductor thin film through an insulating film,
wherein said first gate electrode and said second gate electrode receive a first gate voltage and a second gate voltage, respectively, through wirings which are separately provided,
wherein said first gate electrode on-off controls said channel depending on said first gate voltage, and wherein said second gate electrode actively controls said threshold voltage depending on said second gate voltage to adjust the on-off operation of said thin film transistors.

26. The method according to claim 25, wherein said semiconductor thin film constituting said channel is comprised of polycrystalline silicon which does not contain an impurity effectively affecting the formation of a depletion layer, and has a thickness of 100 nm or less.

27. The method according to claim 26, wherein, in all of the thin film transistors contained in said display portion and said circuit portion, said semiconductor thin film constituting said channel does not contain an impurity effectively affecting the formation of a depletion layer.

28. The method according to claim 25, wherein said semiconductor thin film constituting said channel is comprised of polycrystalline silicon which contains an impurity effectively affecting the formation of a depletion layer, and has a thickness two times or less the maximum of the thickness of said depletion layer.

29. The method according to claim 28, wherein, in all of the thin film transistors contained in said display portion and said circuit portion, said semiconductor thin film constituting said channel contains impurity of the same conductive type effectively affecting the formation of a depletion layer.

30. The method according to claim 25, wherein said second gate electrode actively controls said threshold voltage depending on said second gate voltage applied at least when said thin film transistors off-operate, to thereby decrease a current flowing through said channel when said thin film transistors off-operate, as compared to a current flowing through said channel when said second gate voltage is not applied.

31. The method according to claim 25, wherein said second gate electrode actively controls said threshold voltage depending on said second gate voltage applied at least when said thin film transistors on-operate, to thereby increase a current flowing through said channel when said thin film transistors on-operate, as compared to a current flowing through said channel when said second gate voltage is not applied.

32. A method for driving an electroluminescence display which comprises a substrate having thereon a display portion in which an electroluminescence device and a thin film transistor for driving said electroluminescence device are integrated, and a peripheral circuit portion in which thin film transistors are integrated,
each of said thin film transistors comprising a channel which has a predetermined threshold voltage and on-off operates depending on a gate voltage applied through a wiring, at least a part of said thin film transistors comprising a semiconductor thin film constituting said channel, and a first gate electrode and a second gate electrode, which are disposed on a surface and the other surface of said semiconductor thin film having an insulating film in between,
wherein said first gate electrode and said second gate electrode receive a first gate voltage and a second gate voltage, respectively, through wirings which are separately provided,
wherein said first gate electrode on-off controls said channel depending on said first gate voltage, and wherein said second gate electrode actively controls said threshold voltage depending on said second gate voltage to adjust the on-off operation of said thin film transistors.

33. The method according to claim 32, wherein said semiconductor thin film constituting said channel is comprised of polycrystalline silicon which does not contain an impurity effectively affecting the formation of a depletion layer, and has a thickness of 100 nm or less.

34. The method according to claim 33, wherein, in all of the thin film transistors contained in said display portion and said circuit portion, said semiconductor thin film constituting said channel does not contain an impurity effectively affecting the formation of a depletion layer.

35. The method according to claim 32, wherein said semiconductor thin film constituting said channel is comprised of polycrystalline silicon which contains an impurity effectively affecting the formation of a depletion layer, and has a thickness two times or less the maximum of the thickness of said depletion layer.

36. The method according to claim 35, wherein, in all of the thin film transistors contained in said display portion and said circuit portion, said semiconductor thin film constituting said channel contains impurity of the same conductive type effectively affecting the formation of a depletion layer.

37. The method according to claim 32, wherein said second gate electrode actively controls said threshold voltage depending on said second gate voltage applied at least when said thin film transistors off-operate, to thereby decrease a current flowing through said channel when said thin film transistors off-operate, as compared to a current flowing through said channel when said second gate voltage is not applied.

38. The method according to claim 32, wherein said second gate electrode actively controls said threshold voltage depending on said second gate voltage applied at least when said thin film transistors on-operate, to thereby increase a current flowing through said channel when said thin film transistors on-operate, as compared to a current flowing through said channel when said second gate voltage is not applied.
